(19) United States
(12) Patent Application Publication
(10) Pub. No.: US 2025/0254927 A1
(43) Pub. Date: Aug. 7, 2025

(54) SEMICONDUCTOR DEVICE INCLUDING CRYSTALLINE OXIDE SEMICONDUCTOR AND METHOD FOR FABRICATING THE SAME

(71) Applicant: SK hynix Inc., Gyeonggi-do (KR)

(72) Inventor: Dong Jin KO, Gyeonggi-do (KR)

(21) Appl. No.: 18/732,634

(22) Filed: Jun. 4, 2024

(30) Foreign Application Priority Data
Feb. 7, 2024 (KR) 10-2024-0018665

(51) Int. Cl. H01L 29/786; H01L 23/528; H01L 29/04; H01L 29/66

(52) U.S. Cl. CPC H10D 30/6756; H01L 23/5283; H10D 30/031; H10D 62/40

(57) ABSTRACT

A semiconductor device may include a substrate; a crystalline first oxide semiconductor pattern disposed on the substrate; a gate pattern disposed on the first oxide semiconductor pattern; and a crystalline second oxide semiconductor pattern disposed on the first oxide semiconductor pattern on both sides of the gate pattern. A method for fabricating a semiconductor device may include forming a crystalline first oxide semiconductor pattern on a substrate; forming a gate pattern disposed on the first oxide semiconductor pattern; forming an amorphous oxide semiconductor material on the first oxide semiconductor pattern on both sides of the gate pattern; and performing a crystallization process to transform a part of the amorphous oxide semiconductor material in contact with the first oxide semiconductor pattern into a crystalline second oxide semiconductor pattern.

### CROSS-REFERENCE TO RELATED APPLICATION

The present application claims the benefit of Korean Patent Application No. 10-2024-0018665, filed on Feb. 7, 2024, which is incorporated herein by reference in its entirety.

### BACKGROUND

### 1. Field

Embodiments of the present disclosure relate generally to semiconductor technology and, more particularly, to a semiconductor device including an oxide semiconductor and a method for fabricating the same.

### 2. Discussion of the Related Art

In the related art, amorphous silicon or polysilicon has been mainly used as a semiconductor layer of a semiconductor device such as a transistor. The amorphous silicon has the advantage of being able to secure uniform device characteristics through a relatively inexpensive and simple process, but has the disadvantage of low carrier mobility. The polysilicon may be acquired by crystallizing amorphous silicon and may have relatively high carrier mobility. However, in forming the polysilicon, a recrystallization process may be required and uniform device characteristics may not be secured.

Recently, an oxide semiconductor has been proposed as a semiconductor material having both high carrier mobility being the advantage of polysilicon and uniform device characteristics being the advantage of amorphous silicon.

### SUMMARY

Various embodiments of the present disclosure are directed to providing a semiconductor device having reduced contact resistance of a source/drain region by increasing the thickness of the source/drain region while substantially maintaining the thickness of a channel region of an oxide semiconductor layer, and a method for fabricating the same.

A semiconductor device in accordance with an embodiment of the present disclosure may include a substrate; a crystalline first oxide semiconductor pattern disposed on the substrate; a gate pattern disposed on the first oxide semiconductor pattern; and a crystalline second oxide semiconductor pattern disposed on the first oxide semiconductor pattern on both sides of the gate pattern.

A method for fabricating a semiconductor device in accordance with an embodiment of the present disclosure may include forming a crystalline first oxide semiconductor pattern on a substrate; forming a gate pattern disposed on the first oxide semiconductor pattern; forming an amorphous oxide semiconductor material on the first oxide semiconductor pattern on both sides of the gate pattern; and performing a crystallization process to transform a part of the amorphous oxide semiconductor material in contact with the first oxide semiconductor pattern into a crystalline second oxide semiconductor pattern.

According to embodiments of the present invention disclosure, a crystalline second oxide semiconductor pattern is additionally grown on a crystalline first oxide semiconductor pattern of a source/drain region of an oxide semiconductor layer, so that the thickness of the source/drain region may be increased to reduce contact resistance of the source/drain region.

### BRIEF DESCRIPTION OF THE DRAWINGS

FIGS. 1 to 7 are cross-sectional views for describing a semiconductor device and a method for fabricating the same in accordance with an embodiment of the present disclosure.

FIGS. 8 to 14 are cross-sectional views for describing a semiconductor device and a method for fabricating the same in accordance with another embodiment of the present disclosure.

### DETAILED DESCRIPTION

Various embodiments of the present disclosure are described in detail below with reference to the accompanying drawings.

The drawings may not necessarily be drawn to scale, and in some embodiments, the proportions of at least some of the structures illustrated in the drawings may be exaggerated to clearly show features of the embodiments. When a multilayer structure having two or more layers is disclosed in the drawings or detailed description, since the relative positional relationship or arrangement order of the layers illustrated in the drawings merely reflect a specific embodiment, the embodiments of the present disclosure are not limited thereto and the relative positional relationship or arrangement order of the layers may be changed. The drawings or detailed description of the multilayer structure may not reflect all layers existing in a specific multilayer structure (for example, one or more additional layer may exist between two layers illustrated). For example, when a first layer is located on a second layer or on a substrate in the multilayer structure in the drawings or detailed description, it may not only indicate that the first layer may be directly formed on the second layer or directly formed on the substrate, but also indicate that one or more other layers may exist between the first layer and the second layer, or between the first layer and the substrate.

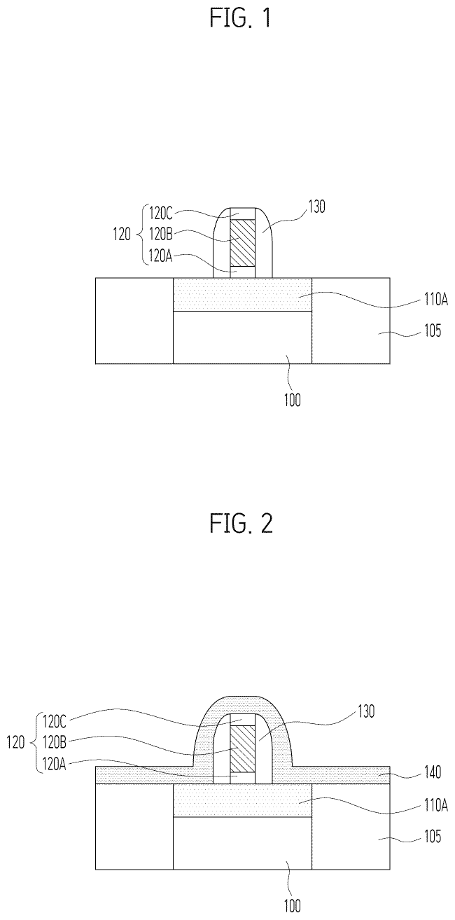

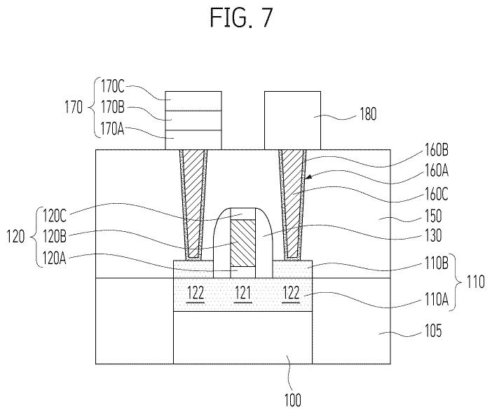

FIGS. 1 to 7 are cross-sectional views for describing a semiconductor device and a method for fabricating the same in accordance with an embodiment of the present disclosure. FIG. 7 illustrates the semiconductor device of the present embodiment, and FIGS. 1 to 6 illustrate intermediate processes for fabricating the semiconductor device of FIG. 7.

The fabricating method is first described.

Referring to FIG. 1, an isolation layer 105 defining an active region may be formed within a substrate 100. The substrate 100 may include various materials such as semiconductor materials and insulating materials. For example, the substrate 100 may be a semiconductor substrate including silicon or silicon-germanium. The isolation layer 105 may be formed as an oxide film by using a high density plasma (HDP) process.

In the present embodiment, the height of a top surface of the substrate 100 may be lower than the height of a top surface of the isolation layer 105. This is for providing a space where a crystalline first oxide semiconductor pattern 110A to be described below is to be formed. The isolation layer 105 may be formed by forming a hard mask pattern (not illustrated) exposing an isolation region on the substrate 100, forming a trench by etching the isolation region of the substrate 100 by using the hard mask pattern as an etch barrier, filling the trench with an insulating material, and then removing the hard mask pattern. A top surface of the insulating material filled in the trench may be located at the same height as a top surface of the hard mask pattern. Accordingly, after the hard mask pattern is removed, the height of the top surface of the substrate 100 may be lower than the height of the top surface of the isolation layer 105.

Subsequently, the crystalline first oxide semiconductor pattern 110A may be formed on the substrate 100. The first oxide semiconductor pattern 110A may be formed by forming an oxide semiconductor material on the substrate 100 and on the isolation layer 105 by a method such as deposition and then removing the oxide semiconductor material so that the top surface of the isolation layer 105 is exposed. In the present embodiment, the height of a top surface of the first oxide semiconductor pattern 110A may be substantially the same as the height of the top surface of the isolation layer 105. However, the embodiments of the present disclosure are not limited thereto, and in a variation of the described embodiment, or in some other embodiments, the height of the top surface of the first oxide semiconductor pattern 110A may be lower than the height of the top surface of the isolation layer 105.

The first oxide semiconductor pattern 110A may be a crystalline metal oxide. The first oxide semiconductor pattern 110A may include at least one metal oxide selected from Group 12, Group 13, and Group 14 metals such as zinc (Zn), indium (In), gallium (Ga), tin (Sn), cadmium (Cd), germanium (Ge), and hafnium (Hf). For example, the first oxide semiconductor pattern 110A may include In—Sn—Ga—Zn oxide, In—Ga—Zn oxide, In—Sn—Zn oxide, In—Al—Zn oxide, Sn—Ga—Zn oxide, Al—Ga—Zn oxide, Sn—Al—Zn oxide, In—Zn oxide, Sn—Zn oxide, Al—Zn oxide, Zn—Mg oxide, Sn—Mg oxide, In—Mg oxide, In—Ga oxide, or the like. Since the first oxide semiconductor pattern 110A is a crystalline metal oxide, a part of an amorphous oxide semiconductor material 140 may be transformed into a crystalline second oxide semiconductor pattern 110B during subsequent annealing of the amorphous oxide semiconductor material 140.

Subsequently, a gate pattern 120 may be formed on the first oxide semiconductor pattern 110A. The gate pattern 120 may include a gate insulating layer 120A, a gate conductive layer 120B, and a gate hard mask layer 120C. The gate pattern 120 may be formed by sequentially depositing a gate insulating material, a gate conductive material, and a gate hard mask material on the first oxide semiconductor pattern 110A and the isolation layer 105, and then selectively etching these materials. In this cross-sectional direction, the gate pattern 120 may have a width smaller than the width of the first oxide semiconductor pattern 110A while overlapping the first oxide semiconductor pattern 110A. The gate insulating layer 120A may include various insulating materials such as silicon oxide, silicon nitride, silicon oxynitride, and aluminum oxide, or a high dielectric material with a higher dielectric constant than silicon oxide, such as zirconium oxide, hafnium oxide, lanthanum oxide, and tantalum oxide, or titanium oxide. The gate conductive layer 120B may include any suitable conductive material such as metal, alloy, or metal compound. The gate hard mask layer 120C may include amorphous carbon, titanium nitride (TiN), tantalum (Ta), titanium (Ti), tungsten (W), silicon oxynitride (SiON), or tetra ethyl oxy silicate (TEOS).

Subsequently, a spacer 130 may be formed on both side walls of the gate pattern 120. For example, the spacer 130 may be formed to cover and contact both side walls of the gate pattern 120, as illustrated in FIG. 2. The spacer 130 may include, for example, a nitride layer.

Referring to FIG. 2, the amorphous oxide semiconductor material 140 may be formed on the process result of FIG. 1 by a method such as deposition. Accordingly, the amorphous oxide semiconductor material 140 may be formed on the gate pattern 120 and the first oxide semiconductor pattern 110A. The amorphous oxide semiconductor material 140 may be conformally deposited to achieve good step coverage. Accordingly, the amorphous oxide semiconductor material 140 may form a substantially conformal layer on the process result of FIG. 1. For example, the substantially conformal layer may vary in thickness by about 10%, 5%, 2%, 1%, or 0.5% or less.

The amorphous oxide semiconductor material 140 may include the same constituent elements as the constituent elements of the first oxide semiconductor pattern 110A, or may include different constituent elements. The amorphous oxide semiconductor material 140 may include at least one metal oxide selected from Group 12, Group 13, and Group 14 metals such as zinc (Zn), indium (In), gallium (Ga), tin (Sn), cadmium (Cd), germanium (Ge), and hafnium (Hf). For example, the amorphous oxide semiconductor material 140 may include In—Sn—Ga—Zn oxide, In—Ga—Zn oxide, In—Sn—Zn oxide, In—Al—Zn oxide, Sn—Ga—Zn oxide, Al—Ga—Zn oxide, Sn—Al—Zn oxide, In—Zn oxide, Sn—Zn oxide, Al—Zn oxide, Zn—Mg oxide, Sn—Mg oxide, In—Mg oxide, In—Ga oxide, or the like.

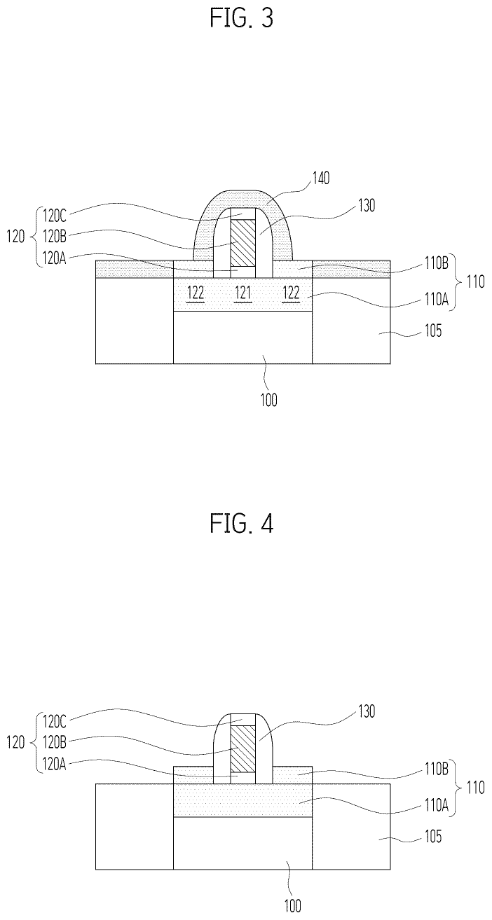

Referring to FIG. 3, by performing a crystallization process, a part of the amorphous oxide semiconductor material 140 in contact with the first oxide semiconductor pattern 110A may be transformed into the crystalline second oxide semiconductor pattern 110B. A part of the amorphous oxide semiconductor material 140 may be transformed into the second oxide semiconductor pattern 110B on the first oxide semiconductor pattern 110A and the remainder may remain unchanged. The crystallization process may include annealing, and similar to an epitaxial growth process during the annealing, a part of the amorphous oxide semiconductor material 140 may be transformed into the crystalline second oxide semiconductor pattern 110B having a crystal structure identical to or similar to the crystalline first oxide semiconductor pattern 110A.

The annealing process may be performed at a sufficient elevated temperature to crystallize the amorphous oxide semiconductor material 140. The annealing process may be performed at a temperature of 300° C. to 500° C. which is relatively a low temperature when compared to other known annealing process in semiconductor fabrication technology. When a part of the amorphous oxide semiconductor material 140 is crystalized, a wet etch rate may be drastically reduced due to an increase in density, so that wet etching selectivity between the amorphous oxide semiconductor material 140 and the crystalline second oxide semiconductor pattern 110B may be obtained. When the first oxide semiconductor pattern 110A and the second oxide semiconductor pattern 110B include the same materials, that is, the same constituent elements, no interface may exist between the first oxide semiconductor pattern 110A and the second oxide semiconductor pattern 110B. Alternatively, the first oxide semiconductor pattern 110A and the second oxide semiconductor pattern 110B may be made of different materials with at least one different constituent element.

The crystalline oxide semiconductor layer 110 including the first oxide semiconductor pattern 110A and the second oxide semiconductor pattern 110B may serve to provide a channel region 121 of a transistor, which is a portion overlapping the gate pattern 120, and source/drain regions 122 serving as both sides of the channel region 121. The channel region 121 of the transistor may include the first oxide semiconductor pattern 110A. The source/drain region 122 of the transistor may include a stack structure of the first oxide semiconductor pattern 110A and the second oxide semiconductor pattern 110B. The second oxide semiconductor pattern 110B may have a top surface that is higher than a bottom surface of the gate pattern 120. Therefore, the thickness of the source/drain region 122 may be relatively increased compared to the channel region 121, and as a result, the contact resistance of the source/drain region 122 may be reduced. Additionally, the second oxide semiconductor pattern 110B may be separated from the gate pattern 120 by the spacer 130.

Referring to FIG. 4, the amorphous oxide semiconductor material 140 which was not crystallized may be removed. The removal of the amorphous oxide semiconductor material 140 may be performed by wet etching. As described above, since the wet etch rate of the second oxide semiconductor pattern 110B is greatly reduced compared to the amorphous oxide semiconductor material 140, the amorphous oxide semiconductor material 140 may be easily selectively removed via this wet etching process.

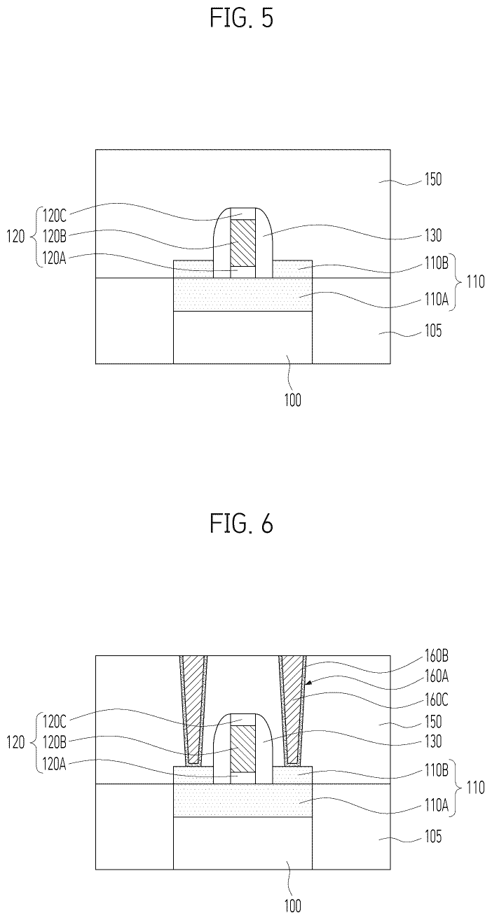

Referring to FIG. 5, an interlayer dielectric layer 150 may be formed to cover the process result of FIG. 4. The interlayer dielectric layer 150 may include any suitable insulating material such as silicon oxide, silicon nitride, and silicon oxynitride, and may be formed to sufficiently cover the gate pattern 120.

Referring to FIG. 6, the interlayer dielectric layer 150 may be selectively etched to form two contact holes 160A, each one on opposite sides of the gate pattern 120. The contact holes 160A may pass through the interlayer dielectric layer 150 and expose two second oxide semiconductor patterns 110B, on either side of the gate pattern 120. Subsequently, a barrier layer 160B may be conformally formed on the bottom (or bottom surface or bottom wall) and inner sidewall of the contact hole 160A. The barrier layer 160B may be conformally formed to cover the entire bottom wall and inner sidewall of the contact hole 160A. The barrier layer 160B may include any suitable conductive material such as titanium nitride and tantalum nitride. The barrier layer 160B may in some embodiments be omitted.

Subsequently, a contact plug 160C may be filled inside the contact hole 160A where the barrier layer 160B is formed. The contact plug 160C may include any suitable conductive material such as metal, alloy, or metal compound. The bottom surfaces of the two contact plugs 160C may be electrically connected to the second oxide semiconductor pattern 110B by directly contacting the second oxide semiconductor pattern 110B. One of the two contact plugs 160C may serve as a source electrode, and the other may serve as a drain electrode. Areas of the bottom surfaces of the two contact plugs 160C may be equal to or less than the area of the second oxide semiconductor pattern 110B.

Referring to FIG. 7, on the interlayer dielectric layer 150, a storage element 170 electrically connected to one of the two contact plugs 160C may be formed, and a conductive line 180 electrically connected to the other of the two contact plugs 160C may be formed.

The storage element 170 is a part that stores data and may include, for example, a capacitor including a lower electrode 170A, an upper electrode 170C, and a dielectric 170B between the lower electrode 170A and the upper electrode 170C. However, the embodiments of the present disclosure are not limited thereto, and the storage element 170 may include a variable resistance element that stores different data by switching between different resistance states. The variable resistance element may have a single layer structure or a multilayer structure including various materials used in, for example, a resistive RAM (RRAM), a phase-change RAM (PRAM), a magneto-resistive RAM (MRAM), a ferroelectric RAM (FRAM), or the like, for example, metal oxide such as transition metal oxide and perovskite-based material, phase change material such as chalcogenide-based material, ferroelectric material, ferromagnetic material, or the like.

The conductive line 180 may include any suitable conductive material such as metal, alloy, and metal compound.

The present embodiment describes a case where the storage element 170 and the conductive line 180 are in direct contact with the two contact plugs 160C; however, the embodiments of the present disclosure are not limited thereto. In another embodiment, another conductive pattern may be interposed between the storage element 170 and the contact plug 160C, and the storage element 170 and the contact plug 160C may be electrically connected through this conductive pattern. Alternatively, in another embodiment, another conductive pattern may be interposed between the conductive line 180 and the contact plug 160C, and the conductive line 180 and the contact plug 160C may be electrically connected through this conductive pattern. The conductive pattern may indicate conductive patterns having various shapes, such as vias.

Through the process described above, the semiconductor device illustrated in FIG. 7 may be fabricated.

Referring again to FIG. 7, the semiconductor device in accordance with an embodiment of the present disclosure may include the substrate 100 on which the isolation layer 105 is formed, the crystalline first oxide semiconductor pattern 110A disposed on the substrate 100, the gate pattern 120 disposed on the first oxide semiconductor pattern 110A, the spacer 130 disposed on both sidewalls of the gate pattern 120, the second oxide semiconductor pattern 110B disposed on the first oxide semiconductor pattern 110A on both sides of the gate pattern 120, and the interlayer dielectric layer 150 covering the gate pattern 120. The semiconductor device may further include the two contact plugs 160C which are connected to the second oxide semiconductor pattern 110B by passing through the interlayer dielectric layer 150. Each contact plug 160C may be formed inside the contact hole 160A. The barrier layer 160B may be formed conformally to cover the bottom and sidewalls of the contact hole 160A and separate the contact plug 160C from interlayer dielectric layer 150 and the second oxide semiconductor pattern 110B. The semiconductor device may further include the storage element 170 and the conductive line 180 disposed on the interlayer dielectric layer 150. The storage element 170 may be connected to a first one of the two contact plugs 160C, and the conductive line 180 may be connected to a second one of the two contact plugs 160C.

The isolation layer 105 may be disposed on both sidewalls of the substrate 100, and the first oxide semiconductor pattern 110A may be disposed on the substrate 100. The gate pattern 120 may be disposed on the first oxide semiconductor pattern 110A, and the second oxide semiconductor pattern 110B may be disposed on both sides of the gate pattern 120. The surface height of the first oxide semiconductor pattern 110A may be the same as the top surface of the isolation layer 105.

When the first oxide semiconductor pattern 110A and the second oxide semiconductor pattern 110B include the same materials, that is, the same constituent elements, no interface may exist between the first oxide semiconductor pattern 110A and the second oxide semiconductor pattern 110B. The first oxide semiconductor pattern 110A and the second oxide semiconductor pattern 110B may be made of different materials with at least one different constituent element. The first oxide semiconductor pattern 110A and the second oxide semiconductor pattern 110B may be stacked to form the crystalline oxide semiconductor layer 110.

The two second oxide semiconductor patterns 110B, the first oxide semiconductor pattern 110A and the gate pattern 120 between the two second oxide semiconductor patterns 110B may form one transistor. The crystalline oxide semiconductor layer 110 including the first oxide semiconductor pattern 110A and the second oxide semiconductor pattern 110B may serve to provide the channel region 121 of the transistor, which is a portion overlapping the gate pattern 120, and the source/drain regions 122 serving as both sides of the channel region 121.

According to the semiconductor device and the method for fabricating the same described above, the following advantages may be obtained.

The thickness of the source/drain region 122 may be increased by additionally growing the crystalline second oxide semiconductor pattern 110B on the crystalline first oxide semiconductor pattern 110A of the source/drain region 122, thereby decreasing the contact resistance of the source/drain region 122. As a result, the contact resistance between the source/drain electrodes and the oxide semiconductor layer 110 may be reduced.

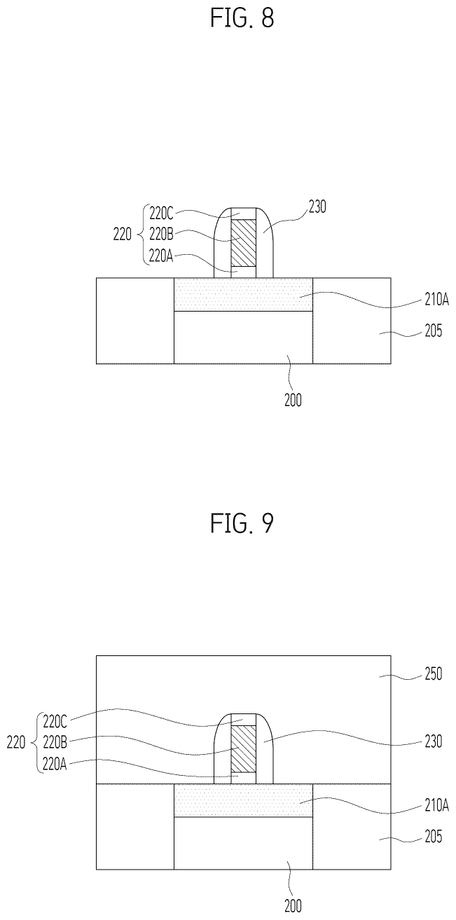

The above embodiment has described the structure in which the crystalline second oxide semiconductor pattern 110B is disposed below the contact hole 160A; however, the embodiments of the present disclosure are not limited thereto. In another embodiment, a structure in which a crystalline second oxide semiconductor pattern is disposed inside a contact hole may also be implemented. This is described with reference to FIGS. 8 to 14 below.

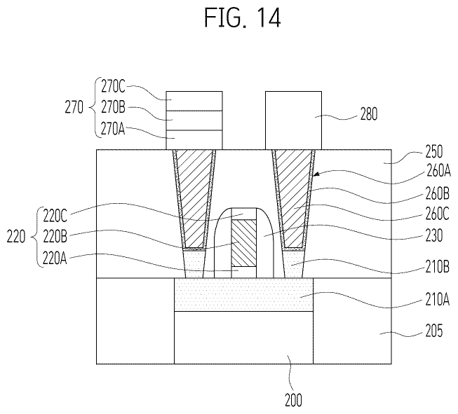

FIGS. 8 to 14 are cross-sectional views for describing a semiconductor device and a method for fabricating the same in accordance with another embodiment of the present disclosure. FIG. 14 illustrates the semiconductor device of the present embodiment, and FIGS. 8 to 13 illustrate intermediate processes for fabricating the semiconductor device in FIG. 14. The following description focuses on differences from the above-described embodiment.

Referring to FIG. 8, an isolation layer 205 defining an active region may be formed within a substrate 200.

Subsequently, a crystalline first oxide semiconductor pattern 210A may be formed on the substrate 200. The height of a top surface of the substrate 200 may be lower than the height of a top surface of the isolation layer 205. The height of a top surface of the first oxide semiconductor pattern 210A may be substantially the same as the height of the top surface of the isolation layer 205. However, the embodiments of the present disclosure are not limited thereto, and the height of the top surface of the first oxide semiconductor pattern 210A may be lower than the height of the top surface of the isolation layer 205.

Subsequently, a gate pattern 220 including a gate insulating layer 220A, a gate conductive layer 220B, and a gate hard mask layer 220C may be formed on the first oxide semiconductor pattern 210A. Subsequently, a spacer 230 may be formed on both sidewalls of the gate pattern 220 to cover and contact both sidewalls of the gate pattern 220.

The structure of FIG. 8 may be substantially the same as the structure of FIG. 1 described above. That is, the substrate 200, the isolation layer 205, the first oxide semiconductor pattern 210A, the gate insulating layer 220A, the gate conductive layer 220B, the hard mask layer 220C, the gate pattern 220, and the spacer 230 may correspond to the substrate 100, the isolation layer 105, the first oxide semiconductor pattern 110A, the gate insulating layer 120A, the gate conductive layer 120B, the hard mask layer 120C, the gate pattern 120, and spacer 130 in the embodiment described above, respectively. Accordingly, this structure may be formed by substantially the same process as the process for forming the structure of FIG. 1 described above.

Referring to FIG. 9, an interlayer dielectric layer 250 may be formed to cover the process result of FIG. 8. The interlayer dielectric layer 250 may be formed to sufficiently cover the gate pattern 220.

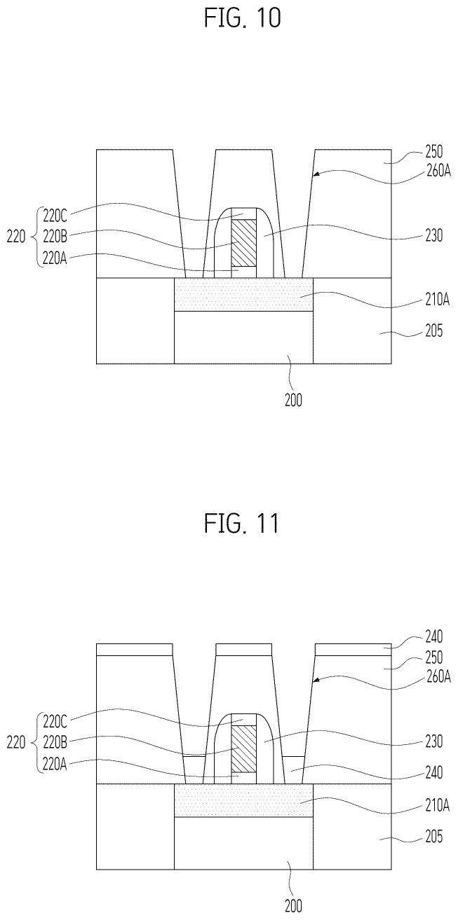

Referring to FIG. 10, the interlayer dielectric layer 250 may be selectively etched to form two contact holes 260A that expose the first oxide semiconductor pattern 210A on both sides of the gate pattern 220, respectively.

Referring to FIG. 11, an amorphous oxide semiconductor material 240 may be deposited on the process result of FIG. 10. For example, the amorphous oxide semiconductor material 240 may be deposited using a physical vapor deposition (PVD). As another example, the amorphous oxide semiconductor material 240 may be deposited using an atomic layer deposition (ALD). The deposition method of the amorphous oxide semiconductor material 240 may not be limited to the PVD and ALD methods and may be variously changed. The amorphous oxide semiconductor material 240 may be conformally formed to cover the process result of FIG. 10 with a thin layer and may not completely fill the contact holes 260A.

When the amorphous oxide semiconductor material 240 is deposited by the PVD method with low step coverage, the amorphous oxide semiconductor material 240 may be formed on the bottom surface of each of the two contact holes 260A. In such a case, the amorphous oxide semiconductor material 240 formed on the bottom surface of the contact hole 260A may be transformed into crystalline in a subsequent crystallization process, and a remaining amorphous oxide semiconductor material 240 deposited on the interlayer dielectric layer 250 is removed.

When the amorphous oxide semiconductor material 240 is deposited by the ALD method with high step coverage, the amorphous oxide semiconductor material 240 may be formed on the sidewalls and bottom surface of each of the two contact holes 260A. In such a case, the amorphous oxide semiconductor material 240 formed on the bottom surface of the contact hole 260A is transformed into crystalline in the subsequent crystallization process, and the amorphous oxide semiconductor material 240 deposited on the sidewalls of the contact hole 260A may remain. Even though a part of the amorphous oxide semiconductor material 240 remains on the sidewalls of the contact hole 260A, since there is enough space for forming a contact plug 260C, a barrier layer 260B and the contact plug 260C may be formed in a subsequent process without removing the amorphous oxide semiconductor material 240 remaining on the sidewalls of the contact hole 260A. However, in order to secure more space for forming the contact plug 260C, the amorphous oxide semiconductor material 240 remaining on the sidewalls of the contact hole 260A may be additionally removed by, for example, wet etching.

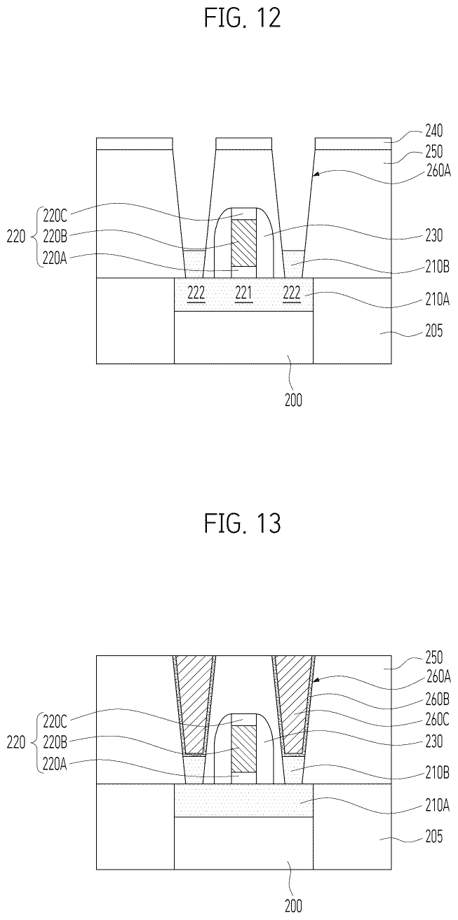

Referring to FIG. 12, by performing a crystallization process, the amorphous oxide semiconductor material 240 at the bottom of the contact hole 260A that is in contact with the first oxide semiconductor pattern 210A may be transformed into a crystalline second oxide semiconductor pattern 210B. In the present embodiment, the amorphous oxide semiconductor material 240 below the contact hole 260A may be transformed into the second oxide semiconductor pattern 210B and the remainder thereof may remain. Accordingly, the second oxide semiconductor pattern 210B may be filled in a lower portion of the contact hole 260A. When the first oxide semiconductor pattern 210A and the second oxide semiconductor pattern 210B include the same materials, that is, the same constituent elements, no interface may exist between the first oxide semiconductor pattern 210A and the second oxide semiconductor pattern 210B. Alternatively, the first oxide semiconductor pattern 210A and the second oxide semiconductor pattern 210B may be made of different materials having at least one different constituent element. The second oxide semiconductor pattern 210B may have a top surface that is higher than a bottom surface of the gate pattern 220.

The crystalline oxide semiconductor layer 210 including the first oxide semiconductor pattern 210A and the second oxide semiconductor pattern 210B may serve to provide a channel region 221 of a transistor, which is a portion overlapping the gate pattern 220, and source/drain regions 222 serving as both sides of the channel region 221. Therefore, the thickness of the source/drain region 222 may be relatively increased compared to the channel region 221, and as a result, the contact resistance of the source/drain region 222 may be reduced.

Referring to FIG. 13, the amorphous oxide semiconductor material 240 that remains without being crystallized may be removed. For example, the amorphous oxide semiconductor material 240 may be removed using wet etching.

Subsequently, the barrier layer 260B may be conformally formed on the bottom and inner sidewall of the contact hole 260A. The contact plug 260C may be formed inside the contact hole 260A where the barrier layer 260B is formed and on the second oxide semiconductor pattern 210B to fill the remainder of the contact hole 260A.

Referring to FIG. 14, a storage element 270 electrically connected to a first one of the two contact plugs 260C may be formed on the interlayer dielectric layer 250. A conductive line 280 electrically connected to a second one of the two contact plugs 260C may also be formed on the interlayer dielectric layer 250.

Through the process described above, the semiconductor device illustrated in FIG. 14 may be fabricated.

Referring again to FIG. 14, the semiconductor device in accordance with another embodiment of the present disclosure may include the substrate 200 on which the isolation layer 205 is formed, the crystalline first oxide semiconductor pattern 210A disposed on the substrate 200, the gate pattern 220 disposed on the first oxide semiconductor pattern 210A, the spacer 230 disposed on both sidewalls of the gate pattern 220, the interlayer dielectric layer 250 covering the gate pattern 220, the contact holes 260A exposing the first oxide semiconductor pattern 210A by passing through the interlayer dielectric layer 250, the second oxide semiconductor pattern 210B filling the lower portion of the contact holes 260A, and the two contact plugs 260C filling the remainder of the contact holes 260A on the second oxide semiconductor pattern 210B. The semiconductor device may further include the storage element 270 and the conductive line 280 disposed on the interlayer dielectric layer 250 and connected to a corresponding one of the two contact plugs 260C, respectively.

According to the present embodiment, a structure in which the second oxide semiconductor pattern 210B is disposed inside the contact hole 260A may be implemented. Even in the present embodiment, all advantages described in the aforementioned embodiment may be acquired.

Although the technical concepts of the present disclosure have been specifically described according to the above embodiments, it should be noted that the above embodiment is for description, not for its limitation. Furthermore, those skilled in the art will understand that various embodiments can be made within the scope of the technical concepts of the present disclosure. Moreover, the embodiments may be combined to form additional embodiments.

What is claimed is:

1. A semiconductor device comprising:
a first oxide semiconductor pattern disposed on a substrate;
a gate pattern disposed on the first oxide semiconductor pattern; and
a second oxide semiconductor pattern disposed on the first oxide semiconductor pattern on both sides of the gate pattern.

2. The semiconductor device of claim 1, further comprising:
an interlayer dielectric layer that covers the gate pattern; and
two contact holes that pass through the interlayer dielectric layer and expose the second oxide semiconductor pattern on both sides of the gate pattern.

3. The semiconductor device of claim 2, further comprising:
two contact plugs filled inside the two contact holes, respectively,
wherein said first and second oxide semiconductor patterns are crystalline.

4. The semiconductor device of claim 3, further comprising:
a storage element electrically connected to one of the two contact plugs; and
a conductive line electrically connected to the other of the two contact plugs,
wherein the storage element and the conductive line are disposed on the interlayer dielectric layer.

5. The semiconductor device of claim 1, further comprising:
an interlayer dielectric layer that covers the gate pattern; and
two contact holes that expose the first oxide semiconductor pattern on both sides of the gate pattern,
wherein the second oxide semiconductor pattern is formed inside a lower portion of each of the two contact holes.

6. The semiconductor device of claim 1, further comprising:
a spacer disposed on both sidewalls of the gate pattern covering both sidewalls of the gate pattern,
wherein the second oxide semiconductor pattern is separated from the gate pattern by the spacer.

7. The semiconductor device of claim 1, wherein the first oxide semiconductor pattern and the second oxide semiconductor pattern include same constituent elements, and no interface exists between the first oxide semiconductor pattern and the second oxide semiconductor pattern.

8. The semiconductor device of claim 1, wherein the first oxide semiconductor pattern and the second oxide semiconductor pattern include different constituent elements.

9. The semiconductor device of claim 1, wherein the substrate includes an isolation layer,
wherein a height of a top surface of the substrate is lower than a height of a top surface of the isolation layer, and
wherein a height of a top surface of the first oxide semiconductor pattern is equal to or less than the height of the top surface of the isolation layer.

10. The semiconductor device of claim 1, wherein the second oxide semiconductor pattern has a top surface that is higher than a bottom surface of the gate pattern.

11. A method for fabricating a semiconductor device, the method comprising:
forming a crystalline first oxide semiconductor pattern on a substrate;
forming a gate pattern disposed on the first oxide semiconductor pattern;
forming an amorphous oxide semiconductor material on the first oxide semiconductor pattern on both sides of the gate pattern; and
performing a crystallization process to transform a part of the amorphous oxide semiconductor material in contact with the first oxide semiconductor pattern into a crystalline second oxide semiconductor pattern.

12. The method of claim 11, wherein the amorphous oxide semiconductor material is formed on the gate pattern and the first oxide semiconductor pattern.

13. The method of claim 12, further comprising, after the crystallization process:
forming an interlayer dielectric layer that covers the gate pattern; and
forming a contact hole that passes through the interlayer dielectric layer and exposes the second oxide semiconductor pattern; and
forming a contact plug that fills the contact hole.

14. The method of claim 11, further comprising, after the forming of the gate pattern and before the forming of the amorphous oxide semiconductor material:
forming an interlayer dielectric layer that covers the gate pattern; and
etching the interlayer dielectric layer to form two contact holes that expose the first oxide semiconductor pattern on both sides of the gate pattern,
wherein the amorphous oxide semiconductor material is formed on a bottom surface of each of the two contact holes.

15. The method of claim 14, wherein the second oxide semiconductor pattern is filled in a lower portion of the contact hole.

16. The method of claim 15, further comprising:
forming a contact plug filling a remainder of the contact hole on the second oxide semiconductor pattern.

17. The method of claim 11, wherein the first oxide semiconductor pattern and the second oxide semiconductor pattern include same constituent elements, and no interface exists between the first oxide semiconductor pattern and the second oxide semiconductor pattern.

18. The method of claim 11, wherein the first oxide semiconductor pattern and the second oxide semiconductor pattern include different constituent elements.

19. The method of claim 11, wherein the crystallization process includes annealing the amorphous oxide semiconductor material at a temperature of 300° C. to 500° C.

20. The method of claim 11, further comprising:
removing the amorphous oxide semiconductor material that is not crystallized.
